(19) United States
(12) Patent Application Publication
(10) Pub. No.: US 2021/0152153 A1
(43) Pub. Date: May 20, 2021

(54) ACOUSTIC WAVE ELEMENT, ACOUSTIC WAVE FILTER, MULTIPLEXER, AND COMMUNICATION APPARATUS

(71) Applicant: KYOCERA Corporation, Kyoto-shi, Kyoto (JP)

(72) Inventor: Tetsuya KISHINO, Nara-shi, Nara (JP)

(21) Appl. No.: 17/046,710

(22) PCT Filed: Apr. 3, 2019
(86) PCT No.: PCT/JP2019/014806

§ 371 Date: Oct. 9, 2020

(30) Foreign Application Priority Data
Apr. 11, 2018 (JP) 2018-075976

(51) Int. Cl. H03H 9/64; H03H 9/05; H03H 9/145; H03H 9/02; H03H 9/25

(52) U.S. Cl. CPC H03H 9/6483; H03H 9/058; H03H 9/6406; H03H 9/02842; H03H 9/25; H03H 9/14541

(57) ABSTRACT

In a SAW element, a piezoelectric layer is laid over a support substrate. An IDT electrode includes a main region and two end regions on two sides of the main region. The end region continues from a portion where electrode finger design is modified up to the end part. A resonance frequency determined by electrode finger design of reflector electrode fingers is lower than a resonance frequency determined by electrode finger design of electrode fingers in the main region. An interval between centers of the electrode fingers in the main region is defined as “a”. Number of electrode fingers configuring the end region is defined as “m”. A distance between a center of an electrode finger among the electrode fingers in the main region which is located on a side closest to the end region and a center of a reflector electrode finger among the reflector electrode fingers which is located on a side closest to the end region is defined as “x”. At this time, the following relationship is satisfied:

0.5×a×(m+1)<x<a×(m+1)

### TECHNICAL FIELD

The present disclosure relates to an acoustic wave element, acoustic wave filter, multiplexer, and communication apparatus. The acoustic wave is for example a SAW (surface acoustic wave).

### BACKGROUND ART

Known in the art is an acoustic wave resonator having an IDT (interdigital transducer) electrode as an excitation electrode and reflectors arranged on the two sides thereof (for example Patent Literature 1). The IDT electrode has pluralities of electrode fingers, while the reflectors have pluralities of reflector electrode fingers. The pluralities of electrode fingers and pluralities of reflector electrode fingers extend in a direction perpendicular to the direction of propagation of the acoustic wave and are arranged in the direction of propagation of the acoustic wave.

Patent Literature 1 proposes an electrode finger design improving resonator characteristics in the acoustic wave element. In this electrode finger design, the pitch of the pluralities of reflector electrode fingers is made longer than the pitch of the pluralities of electrode fingers. Further, the IDT electrode is divided into a main region and end regions on the two sides thereof. Distances between the main region and the reflectors are made shorter compared with a case where the pitch of the pluralities of electrode fingers is made constant (the same as the pitch in the main region) over the entire IDT electrode. For example, the gaps between electrode fingers between the main region and the end regions are made smaller than the gap between the electrode fingers in the main region. Otherwise, the pitches of the plurality of electrode fingers in the end regions are made smaller than the pitch of the electrode fingers in the main region.

### CITATION LIST

### Patent Literature

Patent Literature 1: International Patent Publication No. 2015/080278

### SUMMARY OF INVENTION

An acoustic wave element according to one aspect of the present disclosure is provided with a support substrate, a piezoelectric layer laid over the support substrate, an excitation electrode generating an acoustic wave, and two reflectors. The excitation electrode is located on an upper surface of the piezoelectric layer and includes pluralities of electrode fingers. The two reflectors are located on the upper surface of the piezoelectric layer, includes pluralities of reflector electrode fingers, and sandwich the excitation electrode in a direction of propagation of the acoustic wave. The excitation electrode includes a main region and two end regions. The main region is located between two end parts in the direction of propagation of the acoustic wave. Electrode finger design of the electrode fingers in the main region is uniform. The two end regions continue from portions where electrode finger design is modified from that in the main region up to the end parts and are located on the two sides while sandwiching the main region. A resonance frequency determined by electrode finger design of the reflector electrode fingers in one of the reflectors is lower than a resonance frequency determined by the electrode finger design of the electrode fingers in the main region. When an interval between a center of an electrode finger and a center of an electrode finger neighboring the former electrode finger in the main region is “a”, the number of the electrode fingers configuring one of the end region is “m”, and a distance between a center of an electrode finger among the electrode fingers in the main region which is located on a side closest to the one of the end regions and a center of a reflector electrode finger among the reflector electrode fingers in one of the reflectors which is located on a side closest to the end region is “x”, the following relationship is satisfied:

0.5×a×(m+1)<x<a×(m+1)

An acoustic wave filter according to an aspect of the present disclosure includes one or more serial resonators and one or more parallel resonators which are connected in a ladder shape. At least one of the parallel resonators is configured by the acoustic wave element described above.

A multiplexer according to an aspect of the present disclosure is provided with an antenna terminal, a transmission filter which filters a transmission signal and outputs the result to the antenna terminal, and a receiving filter which filters the reception signal from the antenna terminal. The transmission filter or the receiving filter includes the acoustic wave element described above.

A communication apparatus according to an aspect of the present disclosure includes an antenna, the above multiplexer with the antenna terminal connected to the antenna, and an RF-IC which is electrically connected to the multiplexer.

### BRIEF DESCRIPTION OF DRAWINGS

FIG. 1 is a plan view showing the configuration of an acoustic wave element according to an embodiment of the present disclosure.

FIG. 2 is a view corresponding to a cross-section of a portion cut along the II-II line in the acoustic wave element in FIG. 1.

FIG. 3 is an enlarged plan view showing an enlarged portion of an IDT electrode in the acoustic wave element in FIG. 1.

FIG. 4 is an enlarged plan view showing an enlarged portion of a reflector in the acoustic wave element in FIG. 1.

FIG. 5 is an enlarged view of principal parts showing portions of the IDT electrode and a reflector in the acoustic wave element in FIG. 1.

FIG. 6 is a view showing an example of a method of changing the distance between the IDT electrode and the reflector in FIG. 5.

FIG. 7 is a view schematically representing the relationships of phases in portions of repeated arrangement of a main region and an end region in an acoustic wave resonator in FIG. 6.

FIG. 8A and FIG. 8B are graphs showing measurement values of frequency characteristics in SAW elements according to an example and comparative examples.

FIG. 9A, FIG. 9B, FIG. 9C, and FIG. 9D are graphs showing the results of simulation for SAW elements according to examples and comparative examples and particularly showing an influence by the thickness of a piezoelectric layer.

FIG. 10A, FIG. 10B, FIG. 10C, and FIG. 10D are graphs showing the results of simulation for SAW elements according to examples and comparative examples and particularly showing the influence by the thickness of the piezoelectric layer.

FIG. 11A, FIG. 11B, and FIG. 11C are graphs showing the results of simulation for SAW elements according to examples and comparative examples and particularly showing the influence by the pitch of reflector electrode fingers.

FIG. 12A and FIG. 12B are graphs showing the results of simulation for SAW elements according to examples and a comparative example and particularly showing the influence by the pitch of the reflector electrode fingers.

FIG. 13A, FIG. 13B, FIG. 13C, and FIG. 13D are graphs showing the results of simulation for SAW elements according to examples and comparative examples and particularly showing the influence by a second gap for each pitch of the reflector electrode fingers.

FIG. 14A, FIG. 14B, FIG. 14C, and FIG. 14D are graphs showing the results of simulation for SAW elements according to examples and a comparative example and particularly showing the influence by the second gap for each pitch of the reflector electrode fingers.

FIG. 15A, FIG. 15B, FIG. 15C, and FIG. 15D are graphs showing the results of simulation for SAW elements according to examples and a comparative example and particularly showing the influence by the second pitch for each pitch of the reflector electrode fingers.

FIG. 16A, FIG. 16B, FIG. 16C, and FIG. 16D are graphs showing the results of simulation for SAW elements according to examples and a comparative example and particularly showing the influence by the second pitch for each pitch of the reflector electrode fingers.

FIG. 17A, FIG. 17B, and FIG. 17C are graphs showing the results of simulation for SAW elements according to examples and a comparative example and particularly showing the influence by the second gap for each number of electrode fingers in an end region.

FIG. 18A, FIG. 18B, and FIG. 18C are graphs showing the results of simulation for SAW elements according to examples and a comparative example and particularly showing the influence by the second pitch for each number of the electrode fingers in the end region.

FIG. 19 is a schematic view for explaining a communication apparatus according to an embodiment of the present disclosure.

FIG. 20 is a circuit diagram for explaining a multiplexer according to an embodiment of the present disclosure.

### DESCRIPTION OF EMBODIMENTS

Below, an acoustic wave element, multiplexer, and communication apparatus according to embodiments of the present invention will be explained with reference to the drawings. Note that, the drawings used in the following explanation are schematic ones. Size ratios, etc. in the drawings do not always coincide with the actual ones.

In the acoustic wave element, any direction may be defined as “above” or “below. In the following description, however, for convenience, an orthogonal coordinate system D1-D2-D3 will be defined, and the “upper surface”, “lower surface”, and other terms will be used where the positive side of the D3 direction is the upper part. Note that, the D1 axis is defined so as to be parallel to the direction of propagation of a SAW propagating along the piezoelectric layer which will be explained later, the D2 axis is defined so as to be parallel to the piezoelectric layer and perpendicular to the D1 axis, and the D3 axis is defined so as to be perpendicular to the piezoelectric layer.

<Outline of Configuration of Acoustic Wave Element>

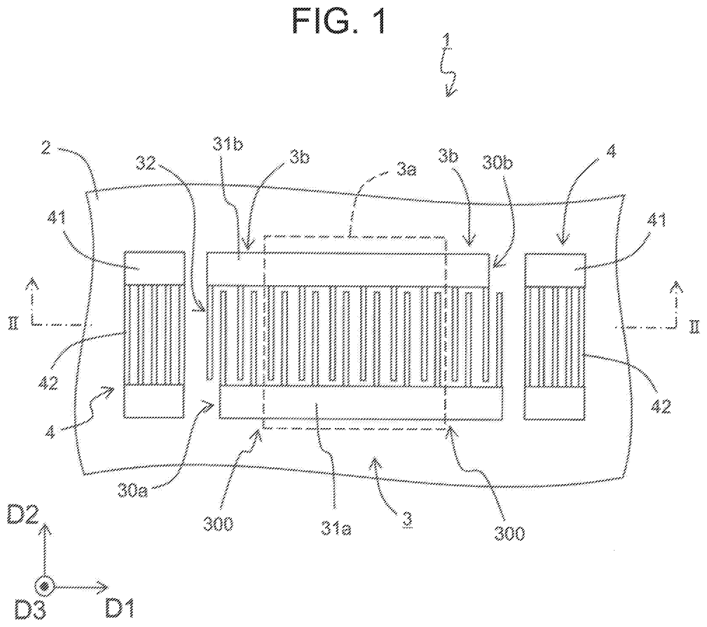

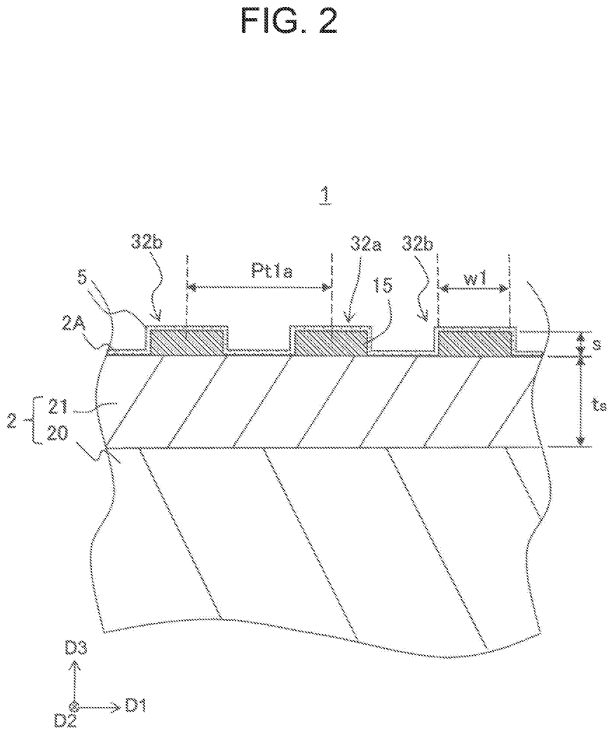

FIG. 1 is a plan view showing the configuration of a SAW element 1 as an acoustic wave element according to one embodiment of the present invention. FIG. 2 is a cross-sectional view of a portion taken along the II-II cut line in FIG. 1. The SAW element 1, as shown in FIG. 1, has a composite substrate 2, an IDT electrode 3 as an excitation electrode, and reflectors 4. The IDT electrode 3 and reflectors 4 are provided on an upper surface 2A of the composite substrate 2.

The SAW element 1 can improve a characteristic of a passing band of a signal by the combination of the configuration of the composite substrate 2, an electrode finger design of two end regions 3b in the IDT electrode 3 which are positioned at the sides of the reflectors 4, and the electrode finger design of the reflectors 4. Below, the requirements will be explained in detail.

(Composite Substrate)

The composite substrate 2, for example, as shown in FIG. 2, has a support substrate 20 and a piezoelectric layer 21 laid over the support substrate 20. The upper surface 2A of the composite substrate 2 is configured by the upper surface of the piezoelectric layer 21.

The piezoelectric layer 21 is for example configured by a single crystal having a piezoelectric characteristic. The single crystal is for example comprised by lithium tantalate (LiTaO₃, below, sometimes abbreviated as “LT”), lithium niobate (LiNbO₃), or crystal (SiO₂). The cut angle may be a suitable one. For example, for LT, a cut angle achieving 30° to 60°-rotated, Y-cut, and X-propagated, or 40° to 55°-rotated, Y-cut, and X-propagated one may be employed. When describing this for confirmation, at this cut angle, the upper surface 2A is perpendicular to a Y′-axis which is rotated around the X-axis from the Y-axis to the Z-axis at an angle of 30° to 60° (or 40° to 55°).

The thickness is of the piezoelectric layer 21 is for example constant. The thickness tₛ is made thinner compared with a case where the substrate is configured by a piezoelectric substance alone. For example, the thickness tₛ is 0.1 to 6 times or 0.5 to 2 times the first pitch Pt1a of the electrode fingers 32 which will be explained later. Further, from another viewpoint, for example, the thickness tₛ is 0.1 μm to 10 μm or 0.5 μm to 5 μm.

The support substrate 20 is for example formed by a material having a smaller thermal expansion coefficient than the material of the piezoelectric layer 21. Due to this, a change of the electrical characteristics of the SAW element 1 due to temperature can be compensated for. As such a material, for example, there can be mentioned silicon or another semiconductor, sapphire or another single crystal, and an aluminum oxide sintered body or another ceramic. Note that, the support substrate 20 may be configured by stacking a plurality of layers which are made of mutually different materials as well.

The thickness of the support substrate 20 is for example constant. The specific value of the thickness may be suitably set in accordance with the specifications demanded from the SAW element 1 and the like. However, the thickness of the support substrate 20 is made greater than the thickness of the piezoelectric layer 21 so that temperature compensation can be suitably carried out and/or the strength of the piezoelectric layer 21 can be reinforced. As one example, the thickness of the support substrate 20 is 100 μm to 300 μm.

Note that, the area of the piezoelectric layer 21 and the area of the support substrate 20 may be the same or may be different (the support substrate 20 may be broader than the piezoelectric layer 21 as well). Note that, in the latter case, a portion of a conductor pattern on the composite substrate 2 (for example, although not particularly shown, terminal for input or for output) may be provided not on the piezoelectric layer 21, but on the support substrate 20.

The piezoelectric layer 21 and the support substrate 20 may be directly laid on each other or may be indirectly laid on each other through an intermediate layer (not shown).

When they are directly laid on each other, for example, a lower surface of the piezoelectric substrate forming the piezoelectric layer 21 and the upper surface of the support substrate 20 may be activated by plasma or a neutral particle beam or the like and the two surfaces directly bonded with each other. Further, for example, CVD (chemical vapor deposition) or another thin film forming method may be used to form a film of the piezoelectric material forming the piezoelectric layer 21 on the support substrate 20.

When provision is made of an intermediate layer, the intermediate layer may be an organic material or may be an inorganic material. As the organic material, for example, a thermosetting resin or another resin may be mentioned. As the inorganic material, for example, there can be mentioned SiO₂, Si₃N₄, AlN, and the like. Further, a stack formed by stacking thin layers which are made of a plurality of different materials may be formed as the intermediate layer as well. The intermediate layer may include a bonding layer for bonding the piezoelectric substrate forming the piezoelectric layer 21 and the support substrate 20 or it may only form an underlying layer of the piezoelectric layer 21 which is formed by a thin film forming method. Further, the intermediate layer may be configured as a layer exerting some effects in terms of acoustics (for example as a layer raising the reflectivity).

For example, when the support substrate 20 is made of silicon, as the intermediate layer between this and the piezoelectric layer 21, there may be an adhesion layer or characteristic adjustment layer such as SiO₂ etc., Si, TaOx layer, etc.

(Electrode)

The IDT electrode 3, as shown in FIG. 1, has a first comb-shaped electrode 30a and second comb-shaped electrode 30b. Note that, in the following explanation, sometimes the first comb-shaped electrode 30a and the second comb-shaped electrode 30b will be simply referred to as the “comb-shaped electrodes 30” and will not be differentiated.

The comb-shaped electrodes 30, as shown in FIG. 1, have two mutually facing bus bars 31a and 31b (below, sometimes simply referred to as the “bus bars 31”) and pluralities of first electrode fingers 32a and second electrode fingers 32b (below, sometimes simply referred to as the “electrode fingers 32”) which extend from one bus bar 31 toward the other bus bar 31 side. Further, the pair of comb-shaped electrodes 30 are arranged so that the first electrode fingers 32a and the second electrode fingers 32b intermesh (intersect) with each other in the direction of propagation of the acoustic wave. Note that, in the bus bars 31, dummy electrodes facing the electrode fingers 32 may be arranged as well. The present embodiment shows a case where no dummy electrodes are arranged.

An acoustic wave is generated and propagated in a direction perpendicular to the pluralities of electrode fingers 32. Accordingly, after considering the crystal orientation of the piezoelectric layer 21, the two bus bars 31 are arranged so as to face each other in a direction crossing the direction in which the acoustic wave is to be propagated. The pluralities of electrode fingers 32 are formed so as to extend in a direction perpendicular with respect to the direction in which the acoustic wave is to be propagated. Note that, the direction of propagation of the acoustic wave is determined according to the orientation of the pluralities of electrode fingers 32 etc. In the present embodiment, however, for convenience, sometimes the orientation of the pluralities of electrode fingers 32 etc. will be explained using the direction of propagation of the acoustic wave as the standard.

The bus bars 31 are for example substantially formed in long shapes so as to linearly extend with constant widths. Accordingly, the edge parts in the bus bars 31 on the sides where they face each other are straight shaped. The pluralities of electrode fingers 32 are for example substantially formed in long shapes so as to linearly extend with constant widths and are arranged at substantially constant intervals in the direction of propagation of the acoustic wave.

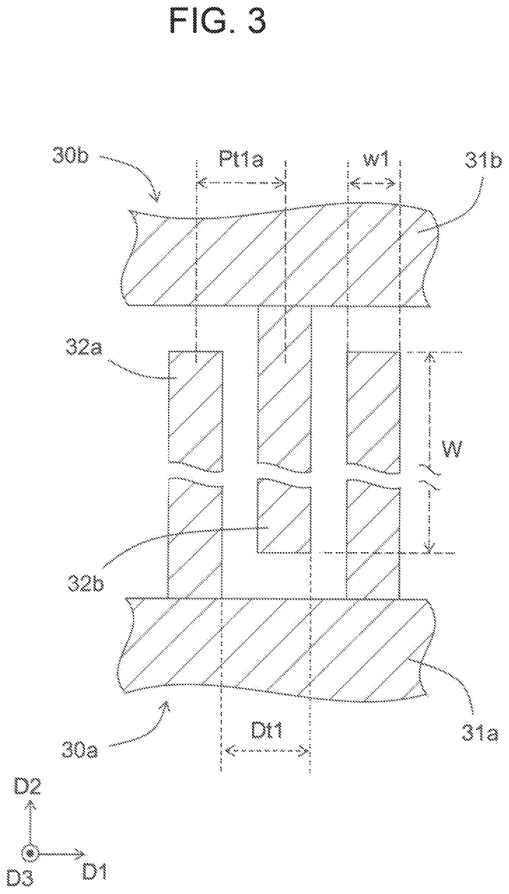

In the IDT electrode 3, as shown in FIG. 1, in the direction of propagation of the acoustic wave, the main region 3a which is arranged between the two ends and the two end regions 3b from the two ends up to the main region 3a are set. The pluralities of electrode fingers 32 in the pair of comb-shaped electrodes 30 configuring the main region 3a in the IDT electrode 3 are set so that the interval between the centers in the widths of neighboring electrode fingers 32 becomes the first pitch Pt1a. The first pitch Pt1a, in the main region 3a, for example, is set so as to be equal to a half wavelength of the wavelength “X” of the acoustic wave at a frequency where resonance should be caused. The wavelength “λ” (that is 2×Pt1a) is for example 1.5 μm to 6 μm. Here, the “first pitch Pt1a”, as shown in FIG. 3, in the direction of propagation of the acoustic wave, designates the interval from the center in the width of a first electrode finger 32a up to the center in the width of a second electrode finger 32b which is adjacent to this first electrode finger 32a. Below, when explaining the pitch, sometimes the “center in the width of an electrode finger 32” will be simply explained as the “center of an electrode finger 32”.

In the electrode fingers 32, the width w1 in the direction of propagation of the acoustic wave is suitably set in accordance with the electrical characteristics etc. which are demanded from the SAW element 1. The width w1 of the electrode fingers 32 is for example 0.3 time to 0.7 time the first pitch Pt1a.

The lengths of the plurality of electrode fingers 32 (lengths from the bus bars 31 to the tip ends) are for example set to substantially the same lengths. Note that, the lengths of the electrode fingers 32 may be changed. For example, they may be made longer or shorter the further advanced in the direction of propagation of the acoustic wave. Specifically, an apodised IDT electrode 3 may be configured by making the lengths of the electrode fingers 32 change with respect to the direction of propagation as well. In this case, horizontal mode spurious emission can be reduced and an electric power resistance can be improved.

The IDT electrode 3 is for example configured by a conductive layer 15 made of metal. As this metal, for example, there can be mentioned Al or an alloy containing Al as a principal ingredient (Al alloy). The Al alloy is for example an Al—Cu alloy. Note that, the IDT electrode 3 may be configured by a plurality of metal layers as well. The various dimensions of the IDT electrode 3 are suitably set in accordance with the electrical characteristics etc. demanded from the SAW element 1. The thickness (D3 direction) of the IDT electrode 3 is for example 50 nm to 600 nm.

The IDT electrode 3 may be directly arranged on the upper surface 2A of the piezoelectric layer 21 or may be arranged on the upper surface 2A of the piezoelectric layer 21 through another member. This other member is for example made of Ti or Cr or an alloy of the same or the like. When the IDT electrode 3 is arranged on the upper surface 2A of the piezoelectric layer 21 through another member, the thickness of this other member is set to a degree of thickness exerting almost no influence upon the electrical characteristics of the IDT electrode 3 (for example, when it is made of Ti, a thickness of 5% of the thickness of the IDT electrode 3).

Further, in order to improve the temperature characteristic of the SAW element 1, a mass addition film may be formed on the electrode fingers 32 configuring the IDT electrode 3. As the mass addition film, for example, use can be made of SiO₂ or the like.

When a voltage is supplied, the IDT electrode 3 excites an acoustic wave (surface acoustic wave) which propagates in the D1 direction (X-axis direction) near the upper surface 2A of the piezoelectric layer 21. The excited acoustic wave is reflected at a boundary with a region where no electrode fingers 32 are arranged (long-shaped region between the adjacent electrode fingers 32). Further, a standing wave having the first pitch Pt1a of the electrode fingers 32 in the main region 3a as the half wavelength is formed. The standing wave is converted to an electrical signal having the same frequency as this standing wave and is extracted by the electrode fingers 32. In this way, the SAW element 1 functions as a 1-port resonator.

The reflectors 4 are formed so that the portions between two or more reflector electrode fingers 42 become slit shapes. That is, the reflectors 4 have reflector bus bars 41 which face each other in a direction crossing the direction of propagation of the acoustic wave and pluralities of reflector electrode fingers 42 which extend in the direction perpendicular to the direction of propagation of the acoustic wave between these reflector bus bars 41 so as to connect the reflector bus bars 41 with each other. The reflector bus bars 41 are for example substantially formed in long shapes so as to linearly extend with constant widths and are arranged parallel to the direction of propagation of the acoustic wave. The interval between the adjacent reflector bus bars 41 for example can be set to substantially the same as the interval between the adjacent bus bars 31 in the IDT electrode 3.

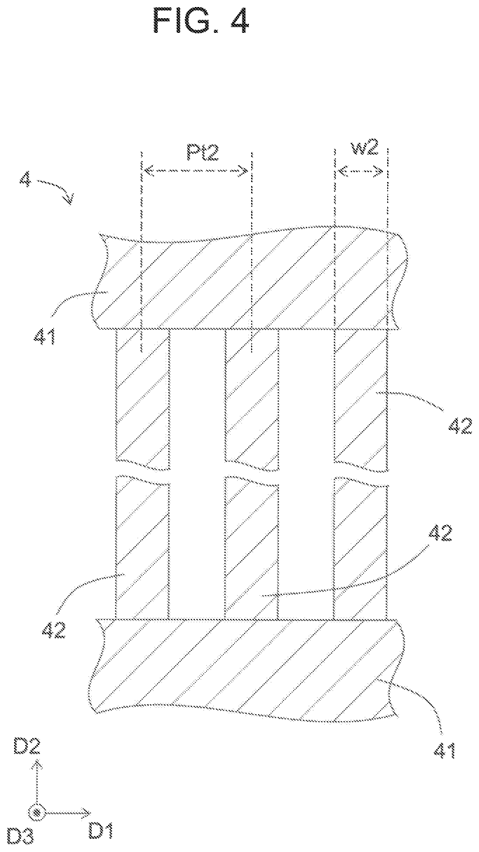

The pluralities of reflector electrode fingers 42 are arranged with a pitch Pt2 reflecting the acoustic wave excited in the IDT electrode 3. The pitch Pt2 will be explained later. Here, the “pitch Pt2”, as shown in FIG. 4, designates the interval between the center of a reflector electrode finger 42 and the center of a reflector electrode finger 42 which is adjacent to the same in the direction of propagation.

Further, the pluralities of reflector electrode fingers 42 are schematically formed in long shapes so as to linearly extend with constant widths. The widths w2 of the reflector electrode fingers 42 for example can be set substantially the same as the widths w1 of the electrode fingers 32. The reflectors 4 are for example formed by the same material for the IDT electrode 3 and are formed to thicknesses equal to that of the IDT electrode 3.

A protective layer 5, as shown in FIG. 2, is provided on the piezoelectric layer 21 so as to cover the tops of the IDT electrode 3 and reflectors 4. Specifically, the protective layer 5 covers the surfaces of the IDT electrode 3 and reflectors 4 and covers the portions in the upper surface 2A which are exposed from the IDT electrode 3 and reflectors 4. The thickness of the protective layer 5 is for example 1 nm to 50 nm.

The protective layer 5 is made of a material having an insulation property and contributes to protection of the IDT electrode 3 and reflectors from corrosion etc. Preferably, the protective layer 5 is formed by SiO₂ or another material making the propagation velocity of the acoustic wave faster when the temperature rises. Due to this, change of the electrical characteristics due to change of temperature of the SAW element 1 can be kept small as well. Note that, the protective layer 5 need not be provided either.

In the SAW element 1 having such a configuration, the electrode finger design in the end regions 3b which are positioned on the sides closer to the end parts than the main region 3a and the electrode finger design of the reflectors 4 are set as follows.

(I) About End Regions 3b in IDT Electrode 3

The IDT electrode 3 is provided with the main region 3a and end regions 3b. The electrode finger design in the main region 3a is uniform, and this electrode finger design is one determining the excitation frequency of the entire IDT electrode 3. That is, matching with the desired excitation frequency, an electrode finger design making design parameters such as the pitch, width, and thickness of the electrode fingers 32 constant is carried out. The end regions 3b designate the regions which continue from the portions modified from the uniform electrode finger design in the main region 3a up to the end parts. Here, the term “modified” means a change of at least one of the design parameters of the electrode fingers 32 of the pitch (interval between the centers of the electrode fingers 32), gap (gap between the electrode fingers 32), width, and thickness. The number of the electrode fingers 32 configuring the main region 3a and the numbers of the electrode fingers 32 configuring the end regions 3b are suitably set so that the resonance frequency according to the electrode finger design in the main region 3a determines the excitation frequency of the entire IDT electrode 3. Specifically, the number of the electrode fingers 32 configuring the main region 3a may be made larger than the numbers of the electrode fingers 32 configuring the end regions 3b.

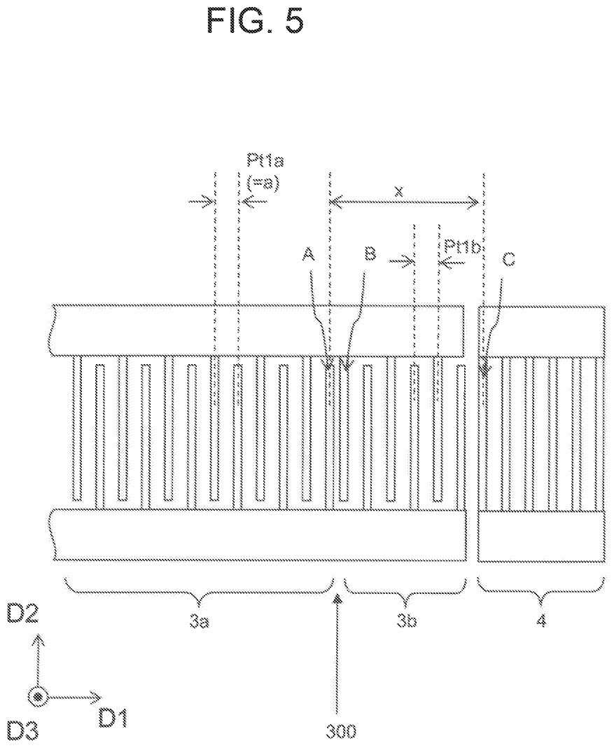

FIG. 5 shows an enlarged cross-sectional view of the principal parts of the IDT electrode 3 and the reflectors 4. Here, in the main region 3a, the electrode finger 32 positioned on the side closest to the end region 3b is defined as the electrode finger “A”. In the end region 3b, the electrode finger 32 which is neighboring the electrode finger “A” and is positioned on the side closest to the main region 3a is defined as the electrode finger “B”. In the reflector 4, the reflector electrode finger 42 positioned on the side closest to the IDT electrode 3 is defined as the reflector electrode finger “C”. Further, in the main region 3a, the interval between the center in the width of an electrode finger 32 and the center in the width of the electrode finger 32 neighboring the former is defined as “a” (first pitch Pt1a described before). The number of the electrode fingers 32 configuring the end region 3b is defined as “m”. The distance between the center in the width of the electrode finger “A” and the center in the width of the reflector electrode finger “C” is “x”. In this case, “x” becomes a value which is larger than 0.5×a×(m+1) and is smaller than a×(m+1).

By configuring them in this way, the distance between the electrode finger “A” and the reflector electrode finger “C” can be made smaller compared with a case where the electrode finger design is not modified between the main region 3a and the end region 3b and where the end region 3b becomes uniform. Due to this, the portion in the end region 3b in which the electrode fingers 32 of the IDT electrode 3 are repeatedly arranged (below, sometimes also referred to as the “portion of arrangement”) can be made closer to the side of the main region 3a.

Here, when the electrode finger design is not modified between the main region 3a and the end region 3b and the end region 3b becomes uniform, a so-called “vertical mode” spurious emission is generated. The spurious emission of the vertical mode is a phenomenon where a high order vibration mode appears in the direction of advance of the surface acoustic wave due to mismatching of phases at the interface between the IDT electrode and the reflector. It becomes a ripple of the impedance characteristic on a lower frequency side than the resonance frequency.

Contrary to this, according to the configuration of the present disclosure, by making the portion of arrangement of the end region 3b closer to the side of the main region 3a, the boundary conditions of the IDT electrode 3 generating the acoustic wave can be changed, therefore the vertical mode can be kept from being generated.

Note that, the number “m” of the electrode fingers 32 in the end region 3b may be made for example 1 or more and less than 70. Within this range, spurious emission caused by the vertical mode can be reduced. Further, the number “m” may be made the 6 to 16 used in the simulation which will be explained later.

(First Method of Adjustment of Distance “x”: Gap Adjustment)

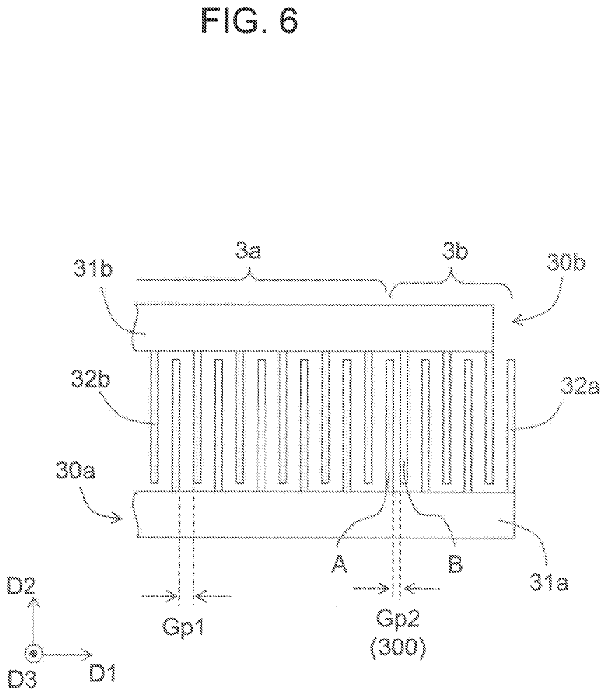

A specific example of changing the distance between the electrode finger “A” and the reflector electrode finger “C” satisfying such conditions will be explained. For example, as shown in FIG. 6, by changing a gap Gp comprised of the gap between a neighboring first electrode finger 32a and second electrode finger 32b, the distance between the electrode finger “A” and the reflector electrode finger “C” can be changed. Specifically, in order to shift the entire portion of arrangement of electrode fingers 32 in the end region 3b with respect to the main region 3a, the arrangement may be set so that the second gap Gp2 comprised of the gap between the electrode finger “A” and the electrode finger “B” becomes narrower than the first gap Gp1 comprised of the gap between the adjacent electrode fingers 32 (first electrode finger 32a and second electrode finger 32b) in the main region 3a. This second gap Gp2, which is smaller than the first gap Gp1, becomes a changed portion 300.

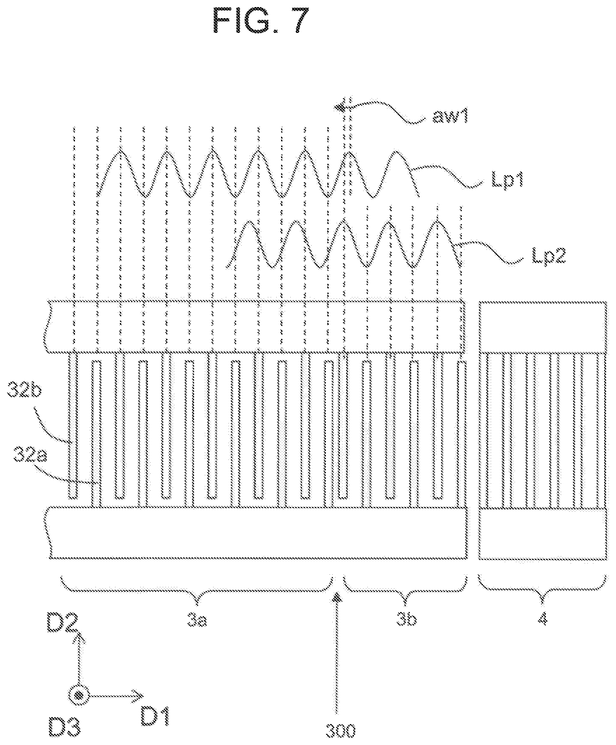

Here, the repeated arrangement in the IDT electrode 3 will be studied. As indicated by lines Lp1 and Lp2 in FIG. 7, the repeated arrangement of the electrode fingers 32 in the IDT electrode 3 indicates for example a repetition of the center of a first electrode finger 32a and the center of the first electrode finger 32a which is positioned next to it across a second electrode finger 32b as one cycle. In this example, the cycle of the repeated arrangement is equal between the main region 3a and the end region 3b. Note that, the lines Lp1 and Lp2 are examples which are set so that the center of the second electrode finger 32b becomes the largest displacement. A repeated cycle caused by such a repeated arrangement will be assumed.

FIG. 7 shows the line Lp1 formed by extending the repeated arrangement of the IDT electrode 3 in the main region 3a to the end part side while keeping the cycle as it is, and the line Lp2 formed by extending the repeated arrangement of the IDT electrode 3 in the end region 3b to the main region 3a side while keeping the cycle as it is. These two repeated arrangements will be compared. As indicated by an arrow aw1, the phase of the repeated cycle assumed by the repeated arrangement of the IDT electrode 3 in the end region 3b shifts to the main region 3a side compared with the phase of the repeated cycle assumed according to the repeated arrangement of the IDT electrode 3 in the main region 3a. According to this configuration, the boundary conditions of the IDT electrode 3 generating the acoustic wave can be changed, therefore the vertical mode can be kept from occurring.

Further, the repeated intervals of the line Lp1 and the line Lp2 are equal, therefore a fine frequency shift caused where the two are different (where the pitch is changed) and/or variation in characteristics due to variation in the process can be reduced.

Further, in FIG. 7, the electrode finger B is not adjacent to the electrode finger which is positioned on the side closest to the reflector 4 (defined as the electrode finger “D”), and the interval between the electrode finger “D” and the electrode finger positioned on the inner side by one place and the interval between the electrode finger “D” and the reflection electrode finger “C” are larger than the interval between the electrode finger “A” and the electrode finger “B”. From this, ESD breakage between the IDT electrode 3 and the reflector 4 can be reduced.

In particular, when the interval between the center of the electrode finger “D” and the center of the reflection electrode finger “C” and the interval between the centers of the electrode fingers in the end region 3b are all equal to the interval between the centers of the electrode fingers in the main region 3a, the arrangement of the reflector and the IDT electrode which easily becomes discontinuous is not disturbed. Further, the arrangement of electrode fingers is regular from the end region in the IDT electrode to the reflector, therefore unwanted electric field concentration is reduced, so reliability can be raised.

(II) About Electrode Finger Design in Reflector

In addition to setting the positional relationships of the electrode finger “A” and the reflector electrode finger “C” described above, the resonance frequency determined by the electrode finger design in the reflector 4 is set lower than the resonance frequency determined by the electrode finger design of the main region 3a in the IDT electrode 3. The resonance frequency of the reflector 4 becomes higher if the pitch Pt2 is made narrower, while becomes lower if the pitch Pt2 is made broader. For this reason, in order to make the resonance frequency of the reflector 4 lower than the resonance frequency of the main region 3a in the IDT electrode 3, the pitch Pt2 of the reflector electrode fingers 42 in the reflector 4 may be set to become broader than the pitch Pt in the main region 3a in the IDT electrode 3 (first pitch Pt1a).

Here, usually the electrode finger design in the reflector 4 is frequently made the same as the electrode finger design in the IDT electrode. That is, the pitch Pt2 is made substantially the same as the pitch Pt1a in many cases. However, in this case, a stop band of the reflector 4 is positioned in the vicinity of the resonance frequency of the IDT electrode, therefore a closing effect by the reflector falls on a lower frequency side than the resonance frequency, and an unintended mode is generated in the reflector. Due to such spurious emission caused by the reflector (below, sometimes also referred to as spurious emission of reflector mode), sometimes a loss was generated on a lower frequency side than the resonance frequency.

Contrary to this, according to the configuration of the present disclosure, by making the pitch Pt2 of the reflector electrode fingers 42 broader than the first pitch Pt1a, the stop band of the reflector 4 is shifted to a lower frequency side, therefore loss due to the reflector mode on a lower frequency side than the resonance frequency can be suppressed.

(Second Method of Adjustment of Distance “x”: Pitch Adjustment)

The conditions for the distance “x” between the electrode finger “A” and the reflector electrode finger “C” in the above (I) may be realized by making the resonance frequency determined by the electrode finger design in the end regions 3b higher than the resonance frequency determined by the electrode finger design in the main region 3a as well.

The resonance frequencies of the IDT electrode 3 positioned in the main region 3a and the end region 3b can be changed by adjusting the pitch Pt1 of the IDT electrode 3. Specifically, the pitch Pt1 may be made narrower in order to make the resonance frequency higher and the pitch Pt1 may be made broader in order to make the resonance frequency lower. For this reason, in the IDT electrode 3, in order to set the resonance frequency in the end region 3b higher than the resonance frequency in the main region 3a, the second pitch Pt1b of the electrode fingers 32 in the end region 3b may be set to become narrower than the first pitch Pt1a of the electrode fingers 32 in the main region 3a.

(Other Method of Adjustment of Distance “x”)

Other than this, although not particularly shown, for example, in the changed portion 300, the widths w1 of the electrode fingers 32 in the IDT electrode 3 may be changed as well. Specifically, the width w1 of the electrode finger 32 (electrode finger B) on the side closest to the main region 3a in the end region 3b is made narrower than the widths w1 of the electrode fingers 32 in the main region 3a. However, the second gap Gp2 and the gap Gp in the end region 3b are set the same as the first gap Gp1 in the main region 3a. By setting this in this way as well, the entirety of the portion of arrangement of the IDT electrode 3 on the side closer to the end part than the changed portion 300 can be shifted to the side of the portion of arrangement of the IDT electrode 3 in the main region 3a. In this case, a region on the side closer to the end part than the electrode finger “A” becomes the end region 3b, and the end region 3b becomes one including the changed portion 300.

Further, for example, the duty of the IDT electrode 3 positioned in the end region 3b may be changed as well. The duty of the IDT electrode 3, as shown in FIG. 3, is a value obtained by dividing the width w1 of a second electrode finger 32b by a distance Dt1 from the end part of the first electrode finger 32a positioned on one side of the second electrode finger 32b in the direction of propagation of the acoustic wave up to the end part on the other side in the second electrode finger 32b. When the duty of the electrode fingers 32 is changed to change the resonance frequency in the end region 3b in this way, the duty may be made smaller in order to make the resonance frequency of the IDT electrode 3 higher while the duty may be made larger in order to make the resonance frequency of the IDT electrode 3 lower. For this reason, the part of the IDT electrode 3 positioned in the end region 3b is set so that its duty becomes smaller than the duty of the part of the IDT electrode 3 positioned in the main region 3a.

As described above, by predetermined design of (I) the end region 3b including the changed portion 300 on the side closer to the end part than the main region 3a and (II) the resonance frequency of the reflector, the spurious emission of the reflector mode is reduced and thereby the spurious emission of the vertical mode increasing in the vicinity of the antiresonance frequency can be reduced. As a result, in particular, spurious emission generated at a frequency lower than the resonance frequency can be reduced.

Further, by setting the resonance frequency of the reflector 4 lower than the resonance frequency in the main region 3a, the reflection frequency region of the reflector 4 can be shifted to a lower frequency side than the resonance frequency in the main region 3a. For this reason, at the time when the SAW element 1 is operated at a frequency lower than the resonance frequency of the main region 3a, leakage of the acoustic wave generated in the main region 3a from the reflector 4 can be prevented. Due to this, a loss at a frequency lower than the resonance frequency of the main region 3a can be reduced.

Further, the piezoelectric layer 21 is relatively thin, therefore spurious emission and/or loss on a higher frequency side of the antiresonance frequency can be reduced. This was confirmed by measurements and simulations which will be explained later.

(Measurement Values of Frequency Characteristics According to Comparative Examples and an Example)

SAW elements (SAW resonators) according to examples and comparative examples were actually prepared, and their frequency characteristics were checked. As a result, it was confirmed that the effects described above were obtained. Specifically, this is as follows.

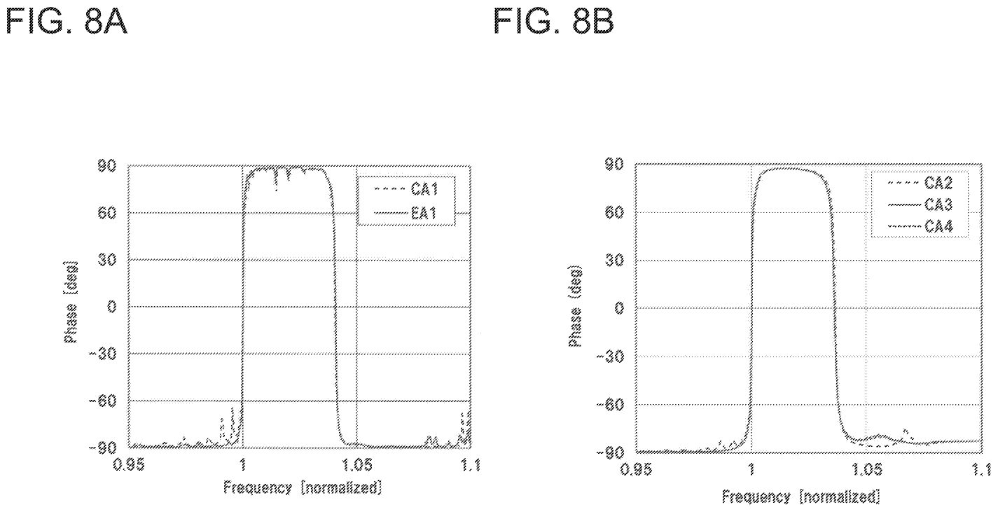

FIG. 8A is a graph showing the frequency characteristics of SAW elements according to Comparative Example CA1 and Example EA1. An abscissa shows the normalized frequency normalized by the resonance frequency. An ordinate shows the phase)(° of impedance.

In the SAW resonator, a resonance point at which the impedance becomes the minimum value and an antiresonance point at which the impedance becomes the maximum value appear. The frequencies at which the resonance point and antiresonance point appear are defined as the resonance frequency and antiresonance frequency. In the SAW resonator, for example, the antiresonance frequency is higher than the resonance frequency. Further, a phase of impedance closer to 90° shows a smaller loss of the SAW resonator at a range between the resonance frequency and the antiresonance frequency, and an impedance phase closer to −90° shows a smaller loss of the SAW resonator at the outside of the former range.

In the example in FIG. 8A, there is a resonance frequency at the normalized frequency 1 and there is an antiresonance frequency near the normalized frequency 1.04. Comparative Example CA1 does not set the above (I) and (II). That is, the pitch of the electrode fingers is constant over the excitation electrode and reflectors. The conditions other than that are basically the same as those in Example EA1.

As shown in FIG. 8A, in Comparative Example CA1, spurious emission is generated near the resonance frequency and on a lower frequency side of the resonance frequency (normalized frequency 0.97 to 1). However, in Example EA1, the spurious emission is reduced. Further, in Comparative Example CA1 and Example EA1, near the antiresonance frequency and on a higher frequency side of the antiresonance frequency (normalized frequency 1.04 to 1.07), no spurious emission is generated, therefore the characteristics of the two substantially coincide.

FIG. 8B is a graph which shows the frequency characteristics of the SAW elements according to Comparative Example CA2, Comparative Example CA3, and Comparative Example CA4 and is similar to FIG. 8A.

In Comparative Examples CA2 to CA4, use is not made of the composite substrate 2, but use is made of a piezoelectric substrate made of a piezoelectric substance alone (that is a relatively thick piezoelectric substance). In Comparative Example CA2, the above (I) and (II) are not set. In Comparative Examples CA3 and CA4, the above (I) and (II) are set. In Comparative Example CA3, the distance “x” is adjusted according to the first method of adjustment (gap adjustment). In Comparative Example CA4, the distance “x” is adjusted according to the second method of adjustment (pitch adjustment).

In Comparative Examples CA3 and CA4, the above (I) and (II) are set. Therefore, compared with Comparative Example CA2, spurious emissions near the resonance frequency and on a lower frequency side of the resonance frequency is reduced. On the other hand, in Comparative Examples CA3 and CA4, compared with comparative Example CA2, the phase of impedance becomes larger than that in Comparative Example CA2 near the antiresonance frequency and on a higher frequency side of the antiresonance frequency, therefore a loss is caused.

(Simulation Computations According to Comparative Examples and Examples)

The frequency characteristics of the SAW elements (SAW resonators) according to various examples and comparative examples were checked by simulation computations. As a result, it was confirmed that the effects described above were obtained. Further, based on the simulation results, one example of the range of values of various parameters was obtained. Specifically, this is as follows.

(Simulation Conditions Common to Comparative Examples and Examples)

The simulation conditions common to all of the following comparative examples and examples will be shown below.

[Piezoelectric Substance: Piezoelectric Layer 21 or piezoelectric substrate]

Material: LT

Cut angle: 42°-rotated, Y-cut, and X-propagated

[IDT Electrode 3]

Material: Al (however, there is an underlying layer made of 6 nm of Ti between the piezoelectric substance and the conductive layer 15)

Thickness (Al layer): 8% of Pt1a×2

Electrode finger 32 in IDT electrode 3:
Number: 150
First pitch Pt1a: 1 μm
Duty (w1/Pt1): 0.5
Intersecting width: 20λ

[Reflector 4]

Material: Al (however, there is an underlying layer made of 6 nm of Ti between the piezoelectric substance and the conductive layer 15)

Thickness (Al layer): 8% of Pt1a×2

Number of reflector electrode finger 42: 30

Note that, the Intersecting width “W” is the distance from the tip end of a first electrode finger 32a up to the tip end of a second electrode finger 32b as shown in FIG. 3.

(Simulation Conditions Common to Examples)

Simulation conditions common to all of the following examples will be shown below.

[Support Substrate]

Material: Silicon (Si)

Cut angle: (111) plane, 0°-propagated, Euler angles (−45°, −54.7°, 0°)

(Simulations Changing Thickness of Piezoelectric Layer)

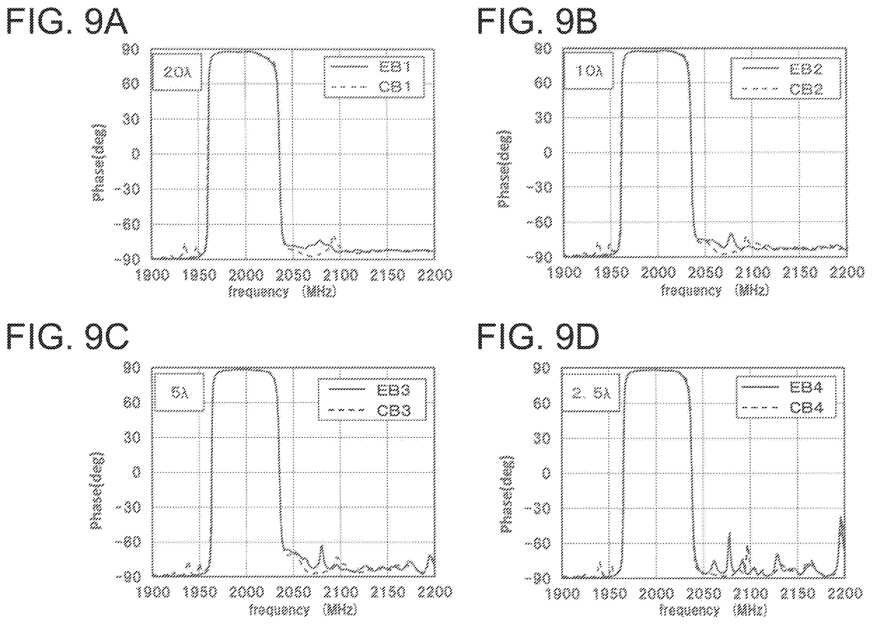

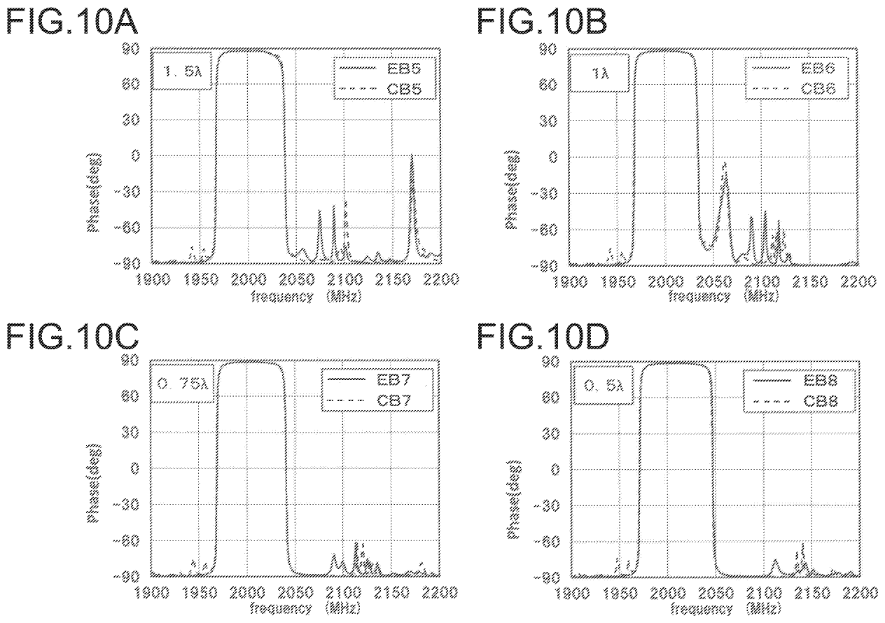

Simulation computations were carried out by setting the thickness of the piezoelectric layer 21 in various ways. FIG. 9A to FIG. 10D are graphs showing the results and are the same graphs as FIG. 8A.

FIG. 9A to FIG. 10D show the results of simulation where the thicknesses of the piezoelectric layers 21 are different from each other. Specifically, the thickness of the piezoelectric layer 21 is 20λ in FIG. 9A, 10λ in FIG. 9B, 5λ in FIG. 9C, 2.5λ in FIG. 9D, 1.5λ in FIG. 10A, 1λ in FIG. 10B, 0.75λ in FIG. 10C, and 0.5λ in FIG. 10D. “λ” is two times of the first pitch Pt1a, that is, 2 μm in the case of the present example.

In these graphs, CB1 to CB8 correspond to comparative examples, and EB1 to EB8 correspond to examples. The comparative examples explained here are different from the examples only in the point that (I) and (II) are not set.

The conditions common to the examples are as follows:

Pitch Pt2 of reflector electrode fingers 42: First pitch Pt1a×1.018

Method of adjustment of distance “x”: First method of adjustment (gap adjustment)

Number “m” of electrode fingers 32 in end region 3b: 10

Second gap Gp2: First gap Gp1×0.85

Second pitch Pt1b in end region 3b: First pitch Pt1a×1

As shown in these graphs, with any thickness, in the examples, compared with the comparative examples, the spurious emissions near the resonance frequency and on a lower frequency side of the resonance frequency are reduced. Further, near the antiresonance frequency and on a higher frequency side of the antiresonance frequency, if the thickness of the piezoelectric layer 21 becomes 1λ or less (FIG. 10B to FIG. 10D), the examples show the characteristics which are equal to or better than those in the comparative examples. Note that, although not particularly shown, the inventors of the present application performed simulation computations also for cases where the thickness of the piezoelectric layer 21 was 0.4λ and 0.3λ and then confirmed that the same effects as those described above were exerted.

(Simulations Changing Pitch of Reflector Electrode Fingers)

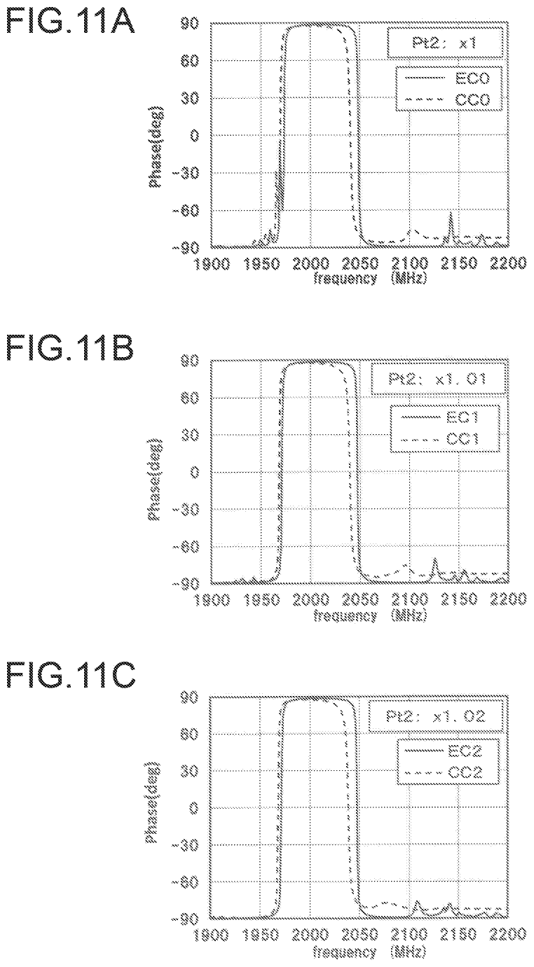

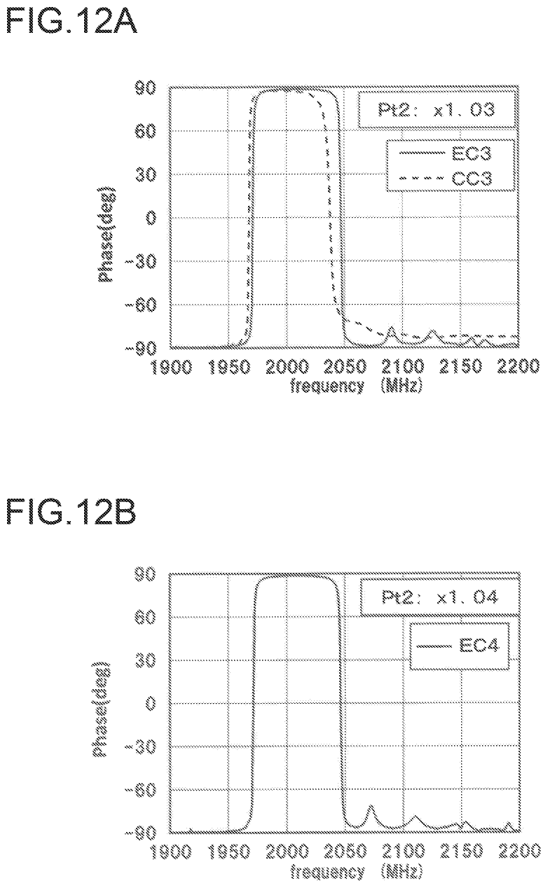

Simulation computations were carried out by changing the pitch Pt2 of the reflector electrode fingers 42 in various ways. FIG. 11A to FIG. 12B are graphs showing the results and are views similar to FIG. 8A.

FIG. 11A to FIG. 12B show the results of simulation when the pitches Pt2 of the reflector electrode fingers 42 are different from each other. Specifically, the size of the pitch Pt2 relative to the first pitch Pt1a in the main region 3a is 1 time in FIG. 11a, 1.01 times in FIG. 11B, 1.02 times in FIG. 11C, 1.03 times in FIG. 12A, and 1.04 times in FIG. 12B.

In FIG. 11A, (II) relating to the reflectors 4 is not set, therefore both of EC0 and CC0 in the graph are comparative examples.

In the other graphs, CC1 to CC3 show comparative examples, and EC1 to EC4 show examples. CC0 to CC3 are different from EC1 to EC3 only in the point that use is made of a piezoelectric substrate thicker than the piezoelectric layer 21.

The conditions common to CC0 to CC3 and EC0 to EC4 are as follows:

Method of adjustment of distance “x”: First method of adjustment (gap adjustment)

Number “m” of electrode fingers 32 in end region 3b: 10

Second pitch Pt1b in end region 3b: First pitch Pt1a×1

The conditions common to EC0 to EC4 are as follows:

Thickness of piezoelectric layer 21: 0.5λ

Note that, the second gap Gp2 is made the optimal value in each example.

It was confirmed from a comparison between Comparative

Example CC0 and Examples EC1 to EC4 (comparison between FIG. 11A and the other graphs) that, even in a case where the thickness of the piezoelectric layer 21 was thin, the spurious emission near the resonance frequency and on a lower frequency side of the resonance frequency was reduced because of the pitch Pt2 of the reflector electrode fingers 42 becoming larger than 1 time the first pitch Pt1a (by combination of the setting of (I) and the setting of (II)).

Further, in CC0 to CC3, the larger the pitch Pt2 of the reflector electrode fingers 42, the larger the impedance phase on a higher frequency side of the antiresonance frequency and the larger the loss. Contrary to this, in EC0 to EC4, this increase of the phase is suppressed, and increase of the loss is suppressed too. It was confirmed from this that, in a case where the pitch Pt2 of the reflector electrode fingers 42 was 1.04 times or less (or less than 1.04 times) the first pitch Pt1a, the effects by combination of the setting of (I) and (II) and setting of the reduction of the thickness of the piezoelectric layer 21 were obtained.

Here, when the thickness of the piezoelectric layer 21 exceeds 1λ, if the pitch of the reflector electrode fingers 42 to 1.02 times or more the first pitch Pt1a, the characteristics on the antiresonance frequency side ends up deteriorating. That is, when the thickness of the piezoelectric layer 21 exceeds 1λ, the extent of adjustment of the pitch of the reflector electrode fingers 42 was very narrow. Contrary to this, when the thickness of the piezoelectric layer 21 is made 1λ or less as in the present example, even if the pitch of the reflector electrode fingers 42 is made 1.02 times or more the first pitch Pt1a, the characteristics in the vicinity of the antiresonance frequency can be maintained in a good state.

Further, it was confirmed that when the thickness of the piezoelectric layer 21 is made 1λ or less, the spurious emission on a lower frequency side than the resonance frequency could be further reduced by setting the pitch of the reflector electrode fingers 42 to 1.02 times or more the first pitch Pt1a. From the above explanation, the pitch of the reflector electrode fingers 42 may be made 1.02 times to 1.04 times the first pitch Pt1a.

Here, the reason why the spurious emission and/or loss are small on a higher frequency side of the antiresonance frequency in the examples will be considered. As a result of measurements and simulations by the inventors for the frequency characteristics by changing the thickness of the piezoelectric layer 21 and changing the electrode finger pattern, the following mechanism is postulated.

That is, when the thickness of the piezoelectric layer 21 is larger than 1λ, there is a tendency for the coupling of a surface wave and a bulk wave to become larger. For this reason, if there is a discontinuous portion in the electrode fingers, vibration energy of the surface wave becomes easier to be radiated as a bulk wave, therefore the loss becomes worse. Contrary to this, when the thickness of the piezoelectric layer 21 is less than 1λ, almost no coupling of the surface wave and bulk wave is caused. Therefore, even if there is a discontinuous portion in the electrode fingers, emission of a bulk wave is kept small, therefore worsening of the loss can be reduced. From the above explanation, by the SAW resonator according to the embodiment, the loss can be reduced without deterioration of the attenuation characteristic on a higher frequency side than the antiresonance frequency where the degradation is supposed. Further, when the thickness of the piezoelectric layer 21 is less than 1λ, sealing of the vibration energy in the resonator is improved, therefore the electro-mechanical coupling coefficient becomes larger. Accordingly, a resonator having a large LI can be obtained.

(Simulations Changing Second Gp for Each Pitch of Reflector Electrode Fingers)

Simulation computations were carried out by setting the pitch Pt2 of the reflector electrode fingers 42 in various ways within the above ranges (larger than 1 time the first pitch Pt1a and not more than 1.04 times) and setting the second gaps Gp2 in various ways for each value of the pitch Pt2.

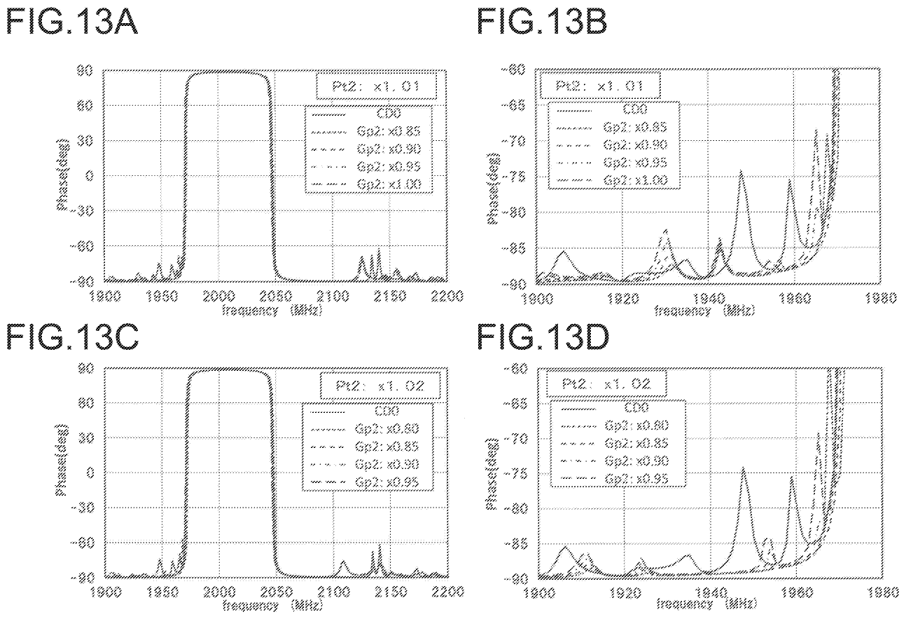

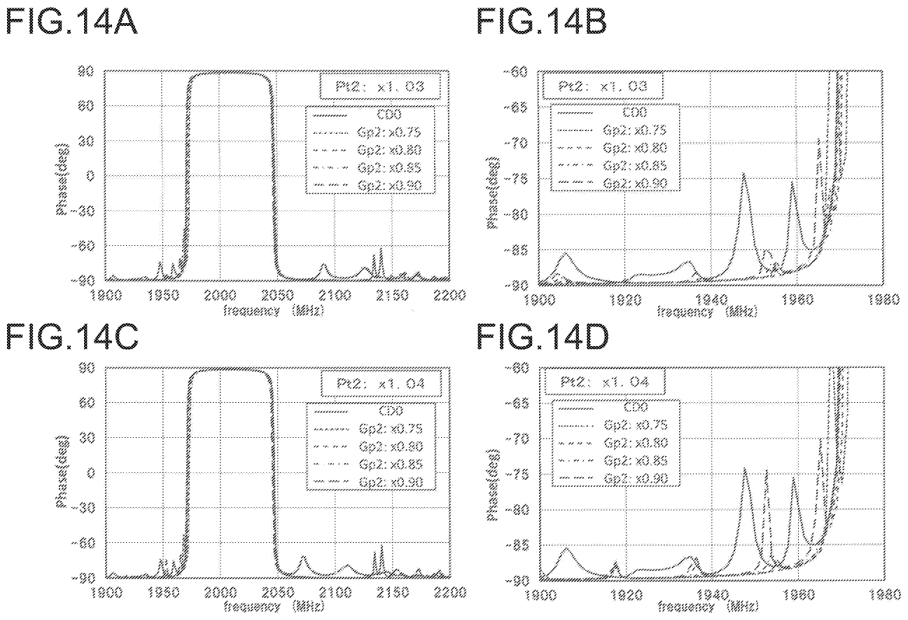

FIG. 13A, FIG. 13C, FIG. 14A, and FIG. 14C are graphs showing the results and are graphs similar to FIG. 8A. Further, FIG. 13B, FIG. 13D, FIG. 14B, and FIG. 14D are enlarged graphs on the resonance frequency side and on a lower frequency side of the resonance frequency in FIG. 13A, FIG. 13C, FIG. 14A, and FIG. 14C.

These graphs show the simulation results when the pitches Pt2 of the reflector electrode fingers 42 are different from each other. Specifically, the size of the pitch Pt2 relative to the first pitch Pt1a in the main region 3a is 1.01 times in FIG. 13A and FIG. 13B, 1.02 times in FIG. 13C and FIG. 13D, 1.03 times in FIG. 14A and FIG. 14B, and 1.04 times in FIG. 14C and FIG. 14D.

In these graphs, CD0 shows a comparative example. This comparative example is different from the examples only in the point that (I) and (II) are not set. The other “Gp2: x, numerical values” basically show examples. Further, the numerical values described show sizes of the second gap Gp2 relative to the first gap Gp1. For example, in a case of “Gp2: ×0.85”, the second gap Gp2 in this example is 0.85 time the first gap Gp1. Note that, “Gp2: ×1.00” in FIG. 13A and FIG. 13B is a comparative example since (I) relative to the distance “x” is not set.

The conditions common to these comparative example and examples are as follows:

Thickness of piezoelectric layer 21: 0.5λ

The conditions common to the examples excluding Comparative Example CD0 (examples performing the first method of adjustment according to the second gap Gp2) are as follows:

Number “m” of electrode fingers 32 in the end region 3b: 10

Note that, the second pitch Pt1b of the electrode fingers 32 in the end region 3b was set at the optimal value in each example.

These graphs show that spurious emission is generated near the resonance frequency and on a lower frequency side of the resonance frequency if the second gap Gp2 is too small or too large. From these results, as in the following way, one example of the range of values of the second gap Gp2 may be found for each pitch Pt2 of the reflector electrode fingers 42.

Case of Pt2=Pt1a×1.01 or

Pt1a×1.005≤Pt2<Pt1a×1.015:

Gp1×0.85<Gp2<Gp1×1.00

Case of Pt2=Pt1a×1.02 or

Pt1a×1.015≤Pt2<Pt1a×1.025:

Gp1×0.80<Gp2<Gp1×0.95

Case of Pt2=Pt1a×1.03 or

Pt1a×1.025≤Pt2<Pt1a×1.035:

Gp1×0.75<Gp2<Gp1×0.90

Case of Pt2=Pt1a×1.04 or

Pt1a×1.035≤Pt2<Pt1a×1.045:

Gp1×0.75<Gp2<Gp1×0.90

Further, as an inclusive range including the ranges described above, the following range may be found:

Gp1×0.75<Gp2<Gp1×1.00

(Simulations Changing Second Pitch in End Regions for Each Pitch of Reflector Electrode Fingers)

Simulation computations were carried out by setting the pitch Pt2 of the reflector electrode fingers 42 in various ways in the same way as that described above and setting the second pitch Pt1b in the end regions 3b for each value of the pitch Pt2.

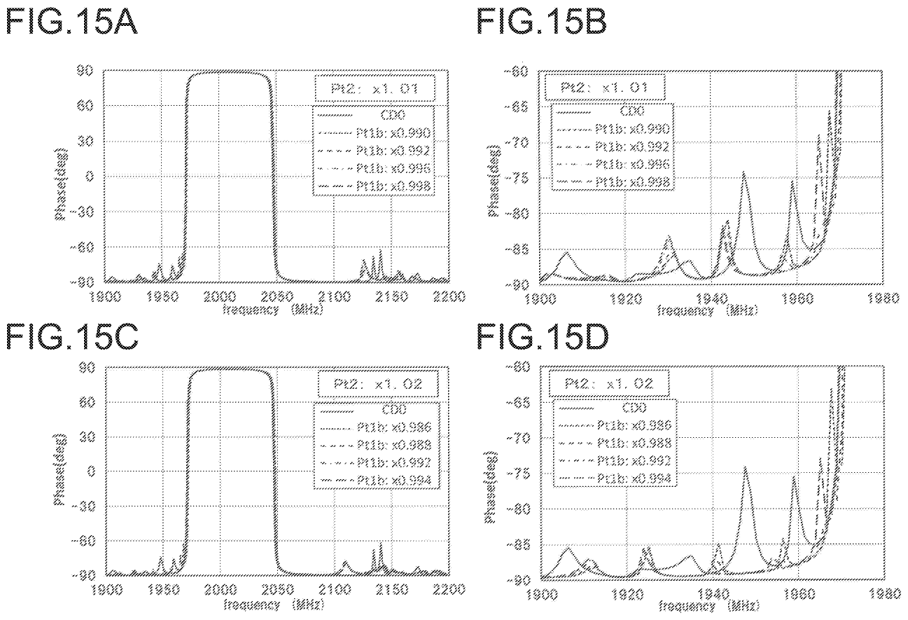

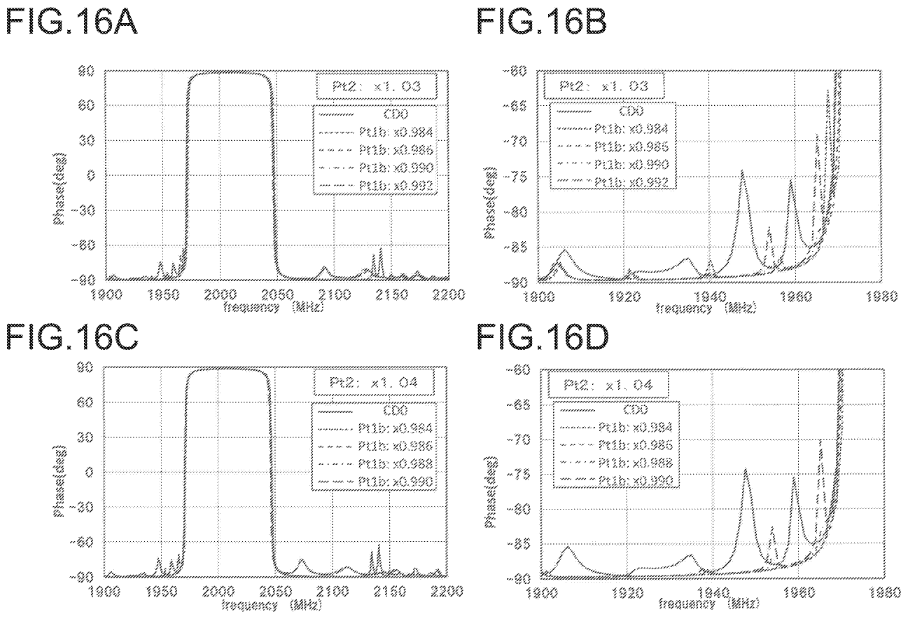

FIG. 15A, FIG. 15C, FIG. 16A, and FIG. 16C are graphs showing the results and are the same graphs as FIG. 8A. Further, FIG. 15B, FIG. 15D, FIG. 16B, and FIG. 16D are enlarged graphs on the resonance frequency side and lower frequency side of the resonance frequency in FIG. 15A, FIG. 15C, FIG. 16A, and FIG. 16C.

These graphs show the results of simulation when the pitches Pt2 of the reflector electrode fingers 42 are different from each other. Specifically, the size of the pitch Pt2 relative to the first pitch Pt1a in the main region 3a is 1.01 times in FIG. 15A, and FIG. 15B, 1.02 times in FIG. 15C and FIG. 15D, 1.03 times in FIG. 16A and FIG. 16B, and 1.04 times in FIG. 16C and FIG. 16D.

In these graphs, CD0 shows the same comparative example as CD0 in FIG. 13A etc. That is, this comparative example is different from the examples only in the point that (I) and (II) are not set. The other “Pt1b: x, numerical values” show examples. Further, the numerical values in the description show sizes of the second pitch Pt1b of the electrode fingers 32 in the end region 3b relative to the first pitch Pt1a of the electrode fingers 32 in the main region 3a. For example, in a case of “Pt1b: ×0.990”, the second pitch Pt1b in this example is 0.990 time the first pitch Pt1a.

The conditions common to these comparative example and examples are as follows:

Thickness of piezoelectric layer 21: 0.5λ

The conditions common to the examples are as follows

Number “m” of electrode fingers 32 in the end region 3b: 10

Note that, the second gap Gp2 was set at the optimal value in each example.

These graphs show that spurious emission is generated near the resonance frequency and on a lower frequency side of the resonance frequency if the second pitch Pt1b is too small or too large. From these results, as will be explained below, one example of the range of values of the second pitch Pt1b may be found for each pitch Pt2 of the reflector electrode fingers 42.

Case of Pt2=Pt1a×1.01 or

Pt1a×1.005≤Pt2<Pt1a×1.015:

Pt1a×0.990<Pt1b<Pt1a×0.998

Case of Pt2=Pt1a×1.02 or

Pt1a×1.015≤Pt2<Pt1a×1.025:

Pt1a×0.986<Pt1b<Pt1a×0.994

Case of Pt2=Pt1a×1.03 or

Pt1a×1.025≤Pt2<Pt1a×1.035:

Pt1a×0.984<Pt1b<Pt1a×0.992

Case of Pt2=Pt1a×1.04 or

Pt1a×1.035≤Pt2<Pt1a×1.045:

Pt1a×0.984≤Pt1b<Pt1a×0.990

Further, as an inclusive range including the ranges described above, the following range may be found.

Pt1a×0.984≤Pt1b<Pt1a×0.998

(Simulations Changing Second Gap for Each Number of Electrode Fingers in End Region)

The simulation computations were carried out by setting the number “m” of the electrode fingers 32 in the end region 3b in various ways and setting the second gap Gp2 in the end region 3b in various ways for each value of the number “m”.

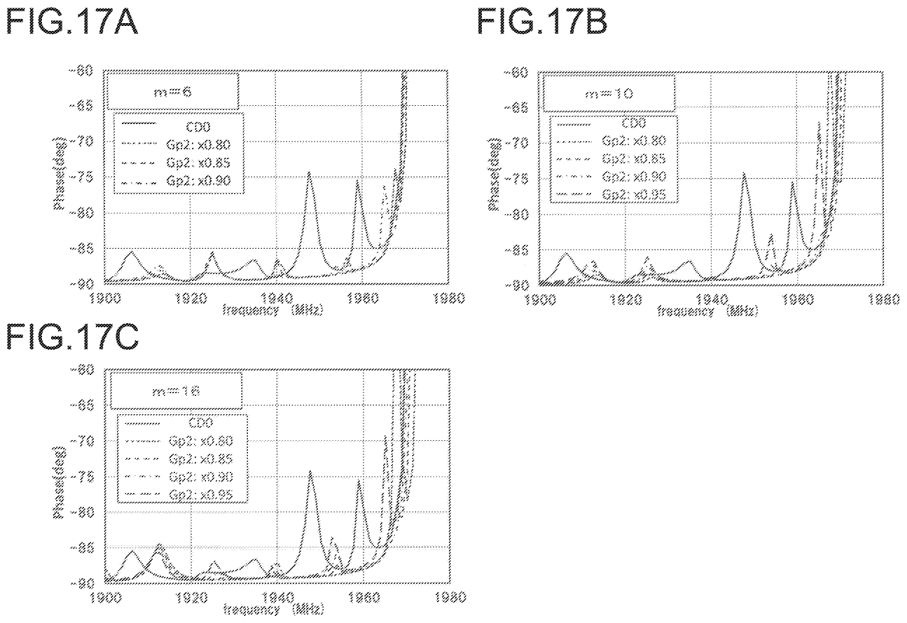

FIG. 17A to FIG. 17C are graphs showing the results and are graphs similar to FIG. 13B. That is, they show the phases of impedance near the resonance frequency and on a lower frequency side of the resonance frequency.

These graphs show the simulation results when the numbers “m” are different from each other. Specifically, the number “m” is 6 in FIG. 17A, 10 in FIG. 17B, and 16 in FIG. 17C.

In these graphs, CD0 shows the same comparative example as CD0 in FIG. 13A etc. That is, this comparative example is different from the examples only in the point that (I) and (II) are not set. The other “Gp2: ×, numerical values” show the values of the second gap Gp2 in the examples in the same way as FIG. 13A.

The conditions common to these comparative example and examples are as follows:

Thickness of piezoelectric layer 21: 0.5×,

The conditions common to the examples are as follows:

Pitch Pt2 of reflector electrode fingers 42: First pitch Pt1a×1.018

Note that, the second pitch Pt1b of the electrode fingers 32 in the end region 3b was set at the optimal value in each example.

These graphs, in the same way as FIG. 13A to FIG. 14D, show that spurious emission is generated near the resonance frequency and on a lower frequency side of the resonance frequency if the second gap Gp2 is too small or too large. From these results, as will be explained below, one example of the range of the second gap Gp2 may be found for each number “m”.

Case of m=6 or m≤8:

Gp1×0.80<Gp2<Gp1×0.90

Case of m=10 or 8<m≤14:

Gp1×0.80<Gp2<Gp1×0.95

Case of m=16 or 14<m≤20:

Gp1×0.80<Gp2<Gp1×0.95

Note that, between the case where the number “m” is 10 (FIG. 17B) and the case where it is 16 (FIG. 17C), the ranges of the second gap Gp2 described above are the same.

Further, as an inclusive range including the ranges described above, the following range may be found:

Gp1×0.80<Gp2<Gp1×0.95

All of the ranges described above are included in the inclusive range (Gp1×0.75<Gp2<Gp1×0.00) obtained from the simulation results (FIG. 13A to FIG. 14D) changing the second gap Gp2 relative to the various pitches Pt2 of the reflector electrode fingers 42.

(Simulations Changing Second Pitch in End Region for Each Number of Electrode Fingers in End Region)

In the same way as that described above, the simulation computations were carried out by setting the number “m” of the electrode fingers 32 in the end region 3b in various ways and setting the second pitch Pt1b in the end region 3b in various ways for each value of the number “m”.

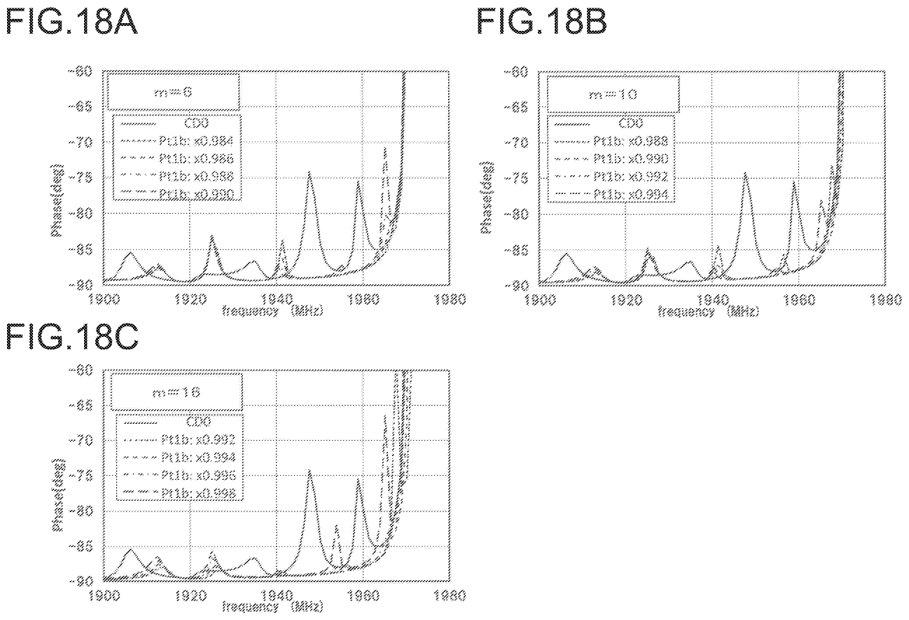

FIG. 18A to FIG. 18C are graphs showing the results and are graphs similar to FIG. 13B. That is, they show the phases of impedance near the resonance frequency and on a lower frequency side of the resonance frequency.

These graphs show the simulation results when the numbers “m” are different from each other. Specifically, the number “m” is 6 in FIG. 18A, 10 in FIG. 18B, and 16 in FIG. 18C.

In these graphs, CD0 shows the same comparative example as CD0 in FIG. 13A etc. That is, this comparative example is different from the examples only in the point that (I) and (II) are not set. The other “Pt1b: x, numerical values” show the values of the second pitch Pt1b in the examples in the same way as FIG. 15A.

The conditions common to these comparative example and examples are as follows:

Thickness of piezoelectric layer 21: 0.5λ,

The conditions common to the examples are as follows:

Pitch Pt2 of reflector electrode fingers 42: First pitch Pt1a×1.018

Note that, the second gap Gp2 was set at the optimal value in each example.

These graphs, in the same way as FIG. 15A to FIG. 16D, show that spurious emission is generated near the resonance frequency and on a lower frequency side of the resonance frequency if the second pitch Pt1b is too small or too large. From these results, as will be explained below, one example of the range of the second pitch Pt1b may be found for each number “m”.

Case of m=6 or m≤118:

Pt1a×0.984<Pt1b<Pt1a×0.990

Case of m=10 or 8<m14:

Pt1a×0.988<Pt1b<Pt1a×0.994

Case of m=16 or 14<m20:

Pt1a×0.992<Pt1b<Pt1a×0.998

Further, as an inclusive range including the ranges described above, the following range may be found:

Pt1a×0.984<Pt1b<Pt1a×0.998

The above inclusive range is included in the inclusive range (Pt1a×0.984≤Pt1b<Pt1a×0.998) obtained from the simulation results (FIG. 15A to FIG. 16D) changing the second gap Gp2 relative to the various pitches Pt2 of the reflector electrode fingers 42.

As explained above, in the present embodiment, the SAW element 1 has the support substrate 20, piezoelectric layer 21, IDT electrode 3, and two reflectors 4. The piezoelectric layer 21 is laid on the support substrate 20. The IDT electrode 3 is positioned on the upper surface 2A of the piezoelectric layer 21 and has pluralities of electrode fingers 32. The two reflectors 4 are positioned on the upper surface 2A of the piezoelectric layer 21 and sandwich the IDT electrode 3 in the direction of propagation of the SAW (D1 axis direction). The IDT electrode 3 has the main region 3a and two end regions 3b. The main region 3a is positioned between the two end parts in the direction of propagation of the SAW and is uniform in the electrode finger design of the electrode fingers 32. The two end regions 3b continue from the portions where the electrode finger design is modified from that for the main region 3a up to the end parts and are positioned on the two sides while sandwiching the main region 3a between them. The reflectors 4 are lower in the resonance frequency determined by the electrode finger design of the reflector electrode fingers 42 than the resonance frequency determined by the electrode finger design of the electrode fingers 32 in the main region 3a. In the main region 3a, the interval between the center of the electrode finger 32 and the center of the electrode finger 32 adjacent to the former is defined as “a”. The number of the electrode fingers 32 configuring an end region 3b is defined as “m”. The distance between the center of the electrode finger 32 among the electrode fingers 32 in the main region 3a which is positioned on the side closest to the end region 3b and the center of the reflector electrode finger 42 among the reflector electrode fingers 42 which is positioned on the side closest to the end region 3b is defined as “x”. At this time, the following relationship is satisfied:

0.5×a×(m+1)<x<a×(m+1)

Accordingly, as already explained, spurious emission near the resonance frequency and on a lower frequency side of the resonance frequency is reduced, and a loss near the antiresonance frequency and on a higher frequency side of the antiresonance frequency can be reduced.

Note that, in the present embodiment, only cases where the design parameters of the electrode finger design (number, intersecting width, pitch, duty, thickness of electrode, frequency, etc.) were specified were shown. However, the art according to the present disclosure has the effect of reducing spurious emission by setting the design values explained above (m, Gp2, Pt1b, etc.) at the optimal values for any parameter of a SAW element.

In the simulation conditions in the embodiment, adjusting one of the second gap Gp2 and the second pitch Pt1b to a predetermined value while making the other the optimal value was touched upon. At this time, the first method of adjustment (making the second gap Gp2 smaller) and the second method of adjustment (making the second pitch Pt1b smaller) may be combined as well.

In the filter and multiplexer, a plurality of resonators having a variety of numbers and intersecting widths are combined and exhibit respective characteristics. The SAW element according to the present disclosure may be applied with respect to the above plurality of resonators. At this time, design can be carried out in the same way as the case where use is made of a conventional acoustic wave element.

Further, when changing design parameters other than the intersecting width (number, frequency, electrode thickness, etc.), the position of the changed portion 300 (number “m” from the end part) gap Gp, and the like may be suitably set at the optimal values. For this, use may be made of a simulation using coupling of modes (COM method). Specifically, the conditions reducing spurious emission well can be found by running simulations while changing the position of the changed portion 300 (number “m” from the end part), the gap Gp, and the like after setting the design parameters of the resonator.

As the number “m” of the electrode fingers 32 configuring the end region 3b, there is an ideal number according to the total number of the electrode fingers 32 configuring the IDT electrode 3. This can be determined according to simulation using the COM method. Further, spurious emission can be reduced even if the number is out of this ideal number. Within a range of the total number (50 to 500) of the electrode fingers 32 configuring the IDT electrode 3 which is generally designed as the SAW element 1, good characteristics can be obtained if the number “m” is about 5 to 20.

<Outline of Configurations of Communication Apparatus and Multiplexer>

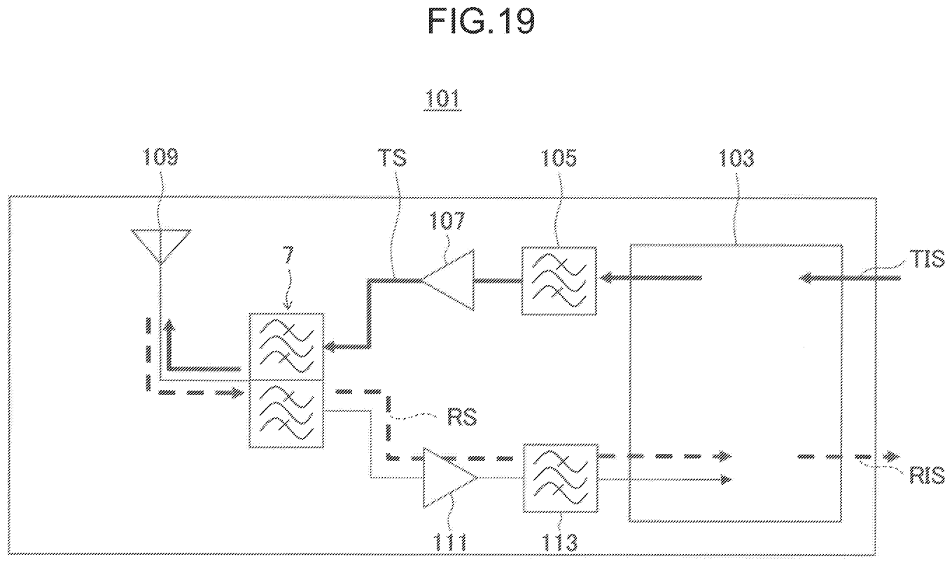

FIG. 19 is a block diagram showing the principal parts of a communication apparatus 101 according to an embodiment of the present disclosure. The communication apparatus 101 is one performing wireless communications utilizing radio waves. The multiplexer 7 (for example duplexer) has a function of branching a signal having a transmission frequency and a signal having a reception frequency in the communication apparatus 101.

In the communication apparatus 101, a transmission information signal TIS including information to be transmitted is modulated and raised in frequency (converted to a high frequency signal having a carrier frequency) by an RF-IC (radio frequency integrated circuit) 103 to become the transmission signal TS. The transmission signal TS is stripped of unwanted components other than the transmission-use passing band by a band pass filter 105, is amplified by an amplifier 107, and is input to the multiplexer 7. The multiplexer 7 strips the unwanted components other than the transmission-use passing band from the input transmission signal TS and outputs the result to an antenna 109. The antenna 109 converts the input electrical signal (transmission signal TS) to a wireless signal and transmits the result.

In the communication apparatus 101, a wireless signal received by the antenna 109 is converted to an electrical signal (reception signal RS) by the antenna 109 and is input to the multiplexer 7. The multiplexer 7 strips unwanted components other than the reception-use passing band from the input reception signal RS and outputs the result to an amplifier 111. The output reception signal RS is amplified by the amplifier 111 and is stripped of unwanted components other than the reception-use passing band by a band pass filter 113. Further, the reception signal RS is boosted down in frequency and demodulated by the RF-IC 103 to become the reception information signal RIS.

Note that, the transmission information signal TIS and reception information signal RIS may be low frequency signals (baseband signals) containing suitable information. For example, they are analog audio signals or digital audio signals. The passing band of the wireless signal may be ones according to various types of standards such as UMTS (universal mobile telecommunications system). The modulation scheme may be phase modulation, amplitude modulation, frequency modulation, or a combination of any two or more among them.

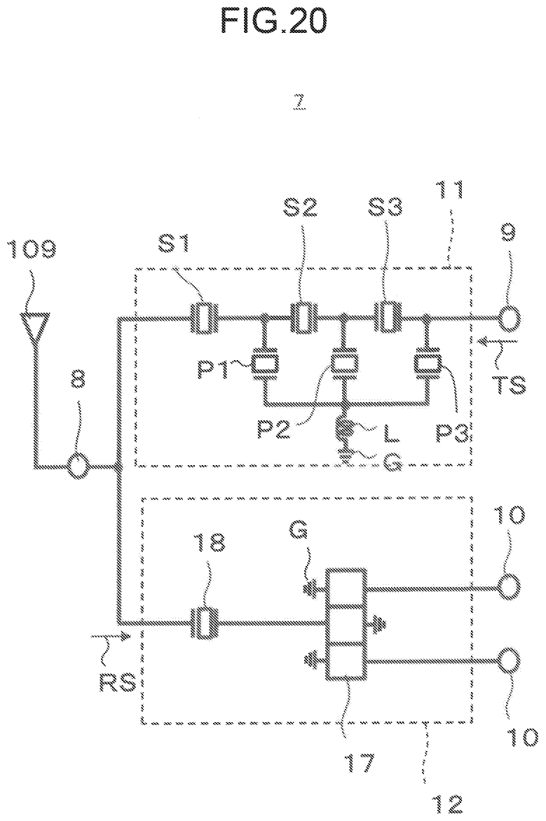

FIG. 20 is a circuit diagram showing the configuration of a multiplexer 7 according to one embodiment of the present disclosure. The multiplexer 7 is the multiplexer 7 used in the communication apparatus 101 in FIG. 19. The SAW element 1 is for example a SAW element configuring a ladder type filter circuit in the transmission filter 11 in the multiplexer 7.

The transmission filter 11 has the composite substrate 2 and serial resonators S1 to S3 and parallel resonators P1 to P3 which are formed on the composite substrate 2.

The multiplexer 7 is mainly configured by an antenna terminal 8, transmission terminal 9, reception terminals 10, transmission filter 11 arranged between the antenna terminal 8 and the transmission terminal 9, and receiving filter 12 arranged between the antenna terminal 8 and the reception terminals 10.

The transmission terminal 9 receives as input the transmission signal TS from the amplifier 107. The transmission signal TS input to the transmission terminal 9 is stripped of unwanted components other than the transmission-use passing band in the transmission filter 11 and is output to the antenna terminal 8. Further, the antenna terminal 8 receives as input the reception signal RS from the antenna 109, unwanted components other than the reception-use passing band are stripped in the receiving filter 12, and the result is output to the reception terminals 10.

The transmission filter 11 is for example configured by a ladder type SAW filter. Specifically, the transmission filter 11 has three serial resonators S1, S2, and S3 which are connected in series between the input side and the output side of the transmission filter 11 and three parallel resonators P1, P2, and P3 which are provided between the serial arm as the wiring for connecting the serial resonators to each other and the reference potential part G. That is, the transmission filter 11 is a ladder type filter having a three-stage configuration. However, in the transmission filter 11, the number of stages of the ladder type filter is any number.

An inductor L is provided between the parallel resonators P1 to P3 and the reference potential part G. By setting the inductance of this inductor L to a predetermined magnitude, an attenuation pole is formed out of the passing band of the transmission signal to thereby make the out-of-band attenuation larger. Each of the plurality of serial resonators S1 to S3 and plurality of parallel resonators P1 to P3 is configured by a SAW resonator.

The receiving filter 12 for example has a multimode type SAW filter 17 and an auxiliary resonator 18 which is connected in series to the input side thereof. Note that, in the present embodiment, the multimode includes a double mode. The multimode type SAW filter 17 has a balance-unbalance conversion function, and the receiving filter 12 is connected to the two reception terminals 10 from which the balanced signals are output. The receiving filter 12 is not limited to one configured by the multimode type SAW filter 17. The receiving filter 12 may be configured by a ladder type filter and/or may be a filter without having a balance-unbalance conversion function.

Between the connection point of the transmission filter 11, receiving filter 12, and antenna terminal 8 and the reference potential part G, an impedance matching-use circuit configured by an inductor or the like may be inserted as well.

By using the SAW element 1 explained above as the SAW resonator of the multiplexer 7, the filter characteristics of the multiplexer 7 can be improved.

Ina so-called ladder type filter used as the transmission side filter in the multiplexer 7, the resonance frequencies of the serial resonators Si to S3 are set near the center of the filter passing band. Further, the parallel resonators P1 to P3 are set in their antiresonance frequencies near the center of the passing band of the filter. Accordingly, when use is made of the acoustic wave element according to the present disclosure for the serial resonators Si to S3, loss and/or ripple near the center of the passing band of the filter and near the boundary on a higher frequency side of the passing band can be improved. Further, when the acoustic wave element according to the present disclosure is used for the parallel resonators P1 to P3, loss and/or ripple near the center of the passing band of the filter and near the boundary on a lower frequency side of the passing band can be improved.

### REFERENCE SIGNS LIST

1 acoustic wave element (SAW element)
2 composite substrate
   2A upper surface
   20 support substrate
   21 piezoelectric layer
3 excitation electrode (IDT electrode)
3a main region
3b end region
   30 comb-shaped electrode
      30a first comb-shaped electrode
      30b second comb-shaped electrode
   31 bus bar
      31a first bus bar
      31b second bus bar
   32 electrode finger
      32a first electrode finger
      32b second electrode finger
   300 changed portion
Pt1 pitch
   Pt1a first pitch
   Pt1b second pitch
Gp gap
   Gp1 first gap
   Gp2 second gap
4 reflector
   41 reflector bus bar
   42 reflector electrode finger
Pt2 pitch
5 protective layer
7 multiplexer
8 antenna terminal
9 transmission terminal
10 reception terminal
11 transmission filter
12 receiving filter
15 conductive layer
17 multimode type SAW filter
18 auxiliary resonator
101 communication apparatus
103 RF-IC
105 bandpass filter
107 amplifier
109 antenna
111 amplifier
113 bandpass filter
S1, S2, S3 serial resonator
P1, P2, P3 parallel resonator

1. An acoustic wave element comprising:
a support substrate,
a piezoelectric layer laid on the support substrate,
an excitation electrode which is located on an upper surface of the piezoelectric layer, comprises pluralities of electrode fingers, and generates an acoustic wave, and
two reflectors which are located on the upper surface of the piezoelectric layer, comprises pluralities of reflector electrode fingers, and sandwich the excitation electrode in a direction of propagation of the acoustic wave between the two reflectors, wherein
the excitation electrode comprises
a main region which is located between two end parts in the direction of propagation of the acoustic wave and is uniform in electrode finger design of the electrode fingers, and
two end regions which continue from portions where electrode finger design is modified from that of the main region up to the end parts and are located on two sides while sandwiching the main region,
a resonance frequency determined by electrode finger design of the reflector electrode fingers in the reflectors is lower than a resonance frequency determined by the electrode finger design of the electrode fingers in the main region, and
when an interval between a center of an electrode finger and a center of an electrode finger adjacent to the former electrode finger in the main region is “a”, the number of the electrode fingers configuring one of the end regions is “m”, and a distance between the center of the electrode finger among the electrode fingers in the main region which is located on a side closest to the one of the end regions and a center of the reflector electrode finger among the reflector electrode fingers in one of the reflectors which is located on a side closest to the one of the end region is “x”, the following relationships is satisfied:
0.5×a×(m+1)<x<a×(m+1).

2. The acoustic wave element according to claim 1, wherein:
the pluralities of electrode fingers comprises a plurality of first electrode fingers and a plurality of second electrode fingers, and
the excitation electrode comprises a first comb-shaped electrode comprising the plurality of first electrode fingers and a second comb-shaped electrode comprises the plurality of second electrode fingers which intermesh with the plurality of first electrode fingers.

3. The acoustic wave element according to claim 1, wherein a second gap comprised of a gap between the electrode finger among the electrode fingers in the main region which is located on the side closest to the one of the end regions and an electrode finger which is adjacent to the former electrode finger and is located on a side closest to the main region among the electrode fingers in the one of the end region is narrower than a first gap which is a gap between two electrode fingers adjoining in the main region.

4. The acoustic wave element according to claim 3, wherein,
an interval between a center of a reflector electrode finger and a center of a reflector electrode finger adjacent to the former reflector electrode finger in the one of the reflectors is larger than 1 time and not more than 1.04 times the interval between the center of the electrode finger and the center of the electrode finger adjacent to the former electrode finger in the main region, and
the second gap is larger than 0.75 time and smaller than 1 time the first gap.

5. The acoustic wave element according to claim 1, wherein, a resonance frequency determined by the electrode finger design of the electrode fingers in the end region is higher than the resonance frequency determined by the electrode finger design of the electrode fingers in the main region.

6. The acoustic wave element according to claim 5, wherein,
an interval between a center of a reflector electrode finger and a center of a reflector electrode finger adjacent to the former reflector electrode finger in the one of the reflectors is larger than 1 time and not more than 1.04 times the interval between the center of the electrode finger and the center of the electrode finger adjacent to the former electrode finger in the main region, and
an interval between a center of an electrode finger and a center of an electrode finger adjacent to the former electrode finger in the one of the end region is 0.984 time or more and is smaller than 0.998 time the interval between the center of the electrode finger and the center of the electrode finger adjacent to the former electrode finger in the main region.

7. The acoustic wave element according to claim 1, wherein a thickness of the piezoelectric layer is 2 times or less the interval between the center of the electrode finger and the center of the electrode finger adjacent to the former electrode finger in the main region.

8. The acoustic wave element according to claim 1, wherein the piezoelectric layer is made of a single crystal of LiTaO₃.

9. The acoustic wave element according to claim 1, wherein an interval between a center of a reflector electrode finger and a center of a reflector electrode finger adjacent to the former reflector electrode finger in the one of the reflector is 1.02 times to 1.04 times relative to the interval between the center of the electrode finger and the center of the electrode finger adjacent to the former electrode finger in the main region.

10. The acoustic wave element according to claim 1, wherein,
an interval between a center of an electrode finger which is located on a side closest to the one of the reflectors in the one of the end region and the center of the reflector electrode finger which is located on the side closest to the one of the end region in the one of the reflector and
an interval between a center of an electrode finger and a center of an electrode finger adjacent to the former electrode finger in the one of the end region
are equal to the interval between the center of the electrode finger and the center of the electrode finger adjacent to the former electrode finger in the main region.

11. An acoustic wave filter comprising one or more serial resonators and one or more parallel resonators which are connected in a ladder shape, wherein at least one of the parallel resonators is configured by the acoustic wave element according to claim 1.

12. A multiplexer comprising:
an antenna terminal,
a transmission filter which filters a transmission signal and outputs the result to the antenna terminal, and
a receiving filter which filters a reception signal from the antenna terminal, wherein
the transmission filter or the receiving filter comprise the acoustic wave element according to claim 1.

13. A communication apparatus comprising:
an antenna,
a multiplexer according to claim 12 in which the antenna terminal is connected to the antenna, and
an RF-IC which is electrically connected to the multiplexer.
